(19) United States
(12) Patent Application Publication
(10) Pub. No.: US 2014/0312512 A1
(43) Pub. Date: Oct. 23, 2014

(54) Semiconductor Device and Method of Forming Bump Interconnect Structure with Conductive Layer Over Buffer Layer

(71) Applicant: STATS ChipPAC, Ltd., Singapore (SG)

(72) Inventor: DaeSik Choi, Seoul (KR)

(21) Appl. No.: 14/321,370

(22) Filed: Jul. 1, 2014

Related U.S. Application Data
(63) Continuation of application No. 13/098,443, filed on Apr. 30, 2011, now abandoned.

(51) Int. Cl. H01L 23/00

(52) U.S. Cl. CPC H01L 24/81; H01L 24/11; H01L 24/16
USPC 257/779; 438/125

(57) ABSTRACT

A semiconductor device has a substrate with a plurality of contact pads. A first insulation layer is formed over the substrate and contact pads. A portion of the first insulating layer is removed to form a toroid-shaped SRO over the contact pads while retaining a central portion of the first insulating layer over the contact pads. The central portion of the first insulating layer can extend above a surface of the first insulating layer outside the first conductive layer. A first conductive layer is formed over the central portion of the first insulating layer and through the SRO in the first insulating layer over the contact pads. The first conductive layer may extend above a surface of the first insulating layer outside the second conductive layer. A semiconductor die is mounted to the substrate with the bumps electrically connected to the first conductive layer.

### CLAIM TO DOMESTIC PRIORITY

The present application is a continuation of U.S. patent application Ser. No. 13/098,443, filed Apr. 30, 2011, which application is incorporated herein by reference.

### FIELD OF THE INVENTION

The present invention relates in general to semiconductor devices and, more particularly, to a semiconductor device and method of forming a bump interconnect structure with a conductive layer over a buffer layer.

### BACKGROUND OF THE INVENTION

Semiconductor devices are commonly found in modern electronic products. Semiconductor devices vary in the number and density of electrical components. Discrete semiconductor devices generally contain one type of electrical component, e.g., light emitting diode (LED), small signal transistor, resistor, capacitor, inductor, and power metal oxide semiconductor field effect transistor (MOSFET). Integrated semiconductor devices typically contain hundreds to millions of electrical components. Examples of integrated semiconductor devices include microcontrollers, microprocessors, charged-coupled devices (CCDs), solar cells, and digital micro-mirror devices (DMDs).

Semiconductor devices perform a wide range of functions such as signal processing, high-speed calculations, transmitting and receiving electromagnetic signals, controlling electronic devices, transforming sunlight to electricity, and creating visual projections for television displays. Semiconductor devices are found in the fields of entertainment, communications, power conversion, networks, computers, and consumer products. Semiconductor devices are also found in military applications, aviation, automotive, industrial controllers, and office equipment.

Semiconductor devices exploit the electrical properties of semiconductor materials. The atomic structure of semiconductor material allows its electrical conductivity to be manipulated by the application of an electric field or base current or through the process of doping. Doping introduces impurities into the semiconductor material to manipulate and control the conductivity of the semiconductor device.

A semiconductor device contains active and passive electrical structures. Active structures, including bipolar and field effect transistors, control the flow of electrical current. By varying levels of doping and application of an electric field or base current, the transistor either promotes or restricts the flow of electrical current. Passive structures, including resistors, capacitors, and inductors, create a relationship between voltage and current necessary to perform a variety of electrical functions. The passive and active structures are electrically connected to form circuits, which enable the semiconductor device to perform high-speed calculations and other useful functions.

Semiconductor devices are generally manufactured using two complex manufacturing processes, i.e., front-end manufacturing, and back-end manufacturing, each involving potentially hundreds of steps. Front-end manufacturing involves the formation of a plurality of die on the surface of a semiconductor wafer. Each die is typically identical and contains circuits formed by electrically connecting active and passive components. The term “semiconductor die” as used herein refers to both the singular and plural form of the word, and accordingly can refer to both a single semiconductor device and multiple semiconductor devices. Back-end manufacturing involves singulating individual die from the finished wafer and packaging the die to provide structural support and environmental isolation.

One goal of semiconductor manufacturing is to produce smaller semiconductor devices. Smaller devices typically consume less power, have higher performance, and can be produced more efficiently. In addition, smaller semiconductor devices have a smaller footprint, which is desirable for smaller end products. A smaller die size can be achieved by improvements in the front-end process resulting in die with smaller, higher density active and passive components. Back-end processes may result in semiconductor device packages with a smaller footprint by improvements in electrical interconnection and packaging materials.

One common technique of interconnecting a semiconductor die with a printed circuit board or other device involves the use of solder bumps. FIG. 1 shows a conventional bump structure 10 with under bump metallization (UBM) formed over semiconductor wafer or die 12, more fully described in U.S. Pat. No. 6,762,503. An electrically conductive layer 14 is formed over an active surface of semiconductor wafer 12, and operates as a contact pad. An insulation or passivation layer 16 is formed over semiconductor wafer 12 and conductive layer 14. A portion of insulating layer 16 is removed by an etching process to expose a portion of conductive layer 14. A multi-layered UBM structure 18 is formed over insulation layer 16 and conductive layer 14. The UBM structure 18 contains an electroless Cu seed layer 20, electroplated Cu layer 22, and solderability enhancement layer 24, such as Ni or Au. Bump 26 is formed over UBM structure 18. The bump interconnect structure in FIG. 1 is susceptible to de-wetting of the UBM and exhibits weak joints and reliability problems.

### SUMMARY OF THE INVENTION

A need exists to improve joint reliability in a bump interconnection structure. Accordingly, in one embodiment, the present invention is a method of making a semiconductor device comprising the steps of providing a substrate including a contact pad formed on a surface of the substrate, forming a first insulating layer in direct contact with the surface of the substrate and contact pad, removing a first portion of the first insulating layer to form an opening within a boundary of the contact pad and extending to the contact pad while leaving a central portion of the first insulating layer extending from the contact pad, and removing a second portion of the first insulating layer to leave a surface of the first insulating layer extending outwardly from the opening below a height of the central portion of the first insulating layer, forming a protective mask in direct contact with the surface of the first insulating layer with an opening in the protective mask extending outside the opening in the first insulating layer, conformally applying a first conductive layer within the opening in the protective mask and in direct contact with the surface and central portion of the first insulating layer and through the opening in the first insulating layer in direct contact with the contact pad, providing a semiconductor die including a bump formed over the semiconductor die, and bonding the bump to the first conductive layer with the central portion of the first insulating layer extending into the bump.

In another embodiment, the present invention is a method of making a semiconductor device comprising the steps of providing a substrate including a contact pad formed on a surface of the substrate, forming a first insulating layer in direct contact with the surface of the substrate and contact pad, removing a portion of the first insulating layer to form an opening extending to the contact pad while leaving a central portion of the first insulating layer extending from the contact pad, forming a protective mask in direct contact with the surface of the first insulating layer with an opening in the protective mask extending outside the opening in the first insulating layer, depositing a conductive material to completely fill the opening in the protective mask from the contact pad to a surface of the protective mask, and disposing a semiconductor die over the substrate and electrically connected to the conductive material.

In another embodiment, the present invention is a method of making a semiconductor device comprising the steps of providing a substrate including a contact pad formed on a surface of the substrate, forming a first insulating layer in direct contact with the surface of the substrate and contact pad, removing a first portion of the first insulating layer to form an opening extending to the contact pad while leaving a central portion of the first insulating layer extending from the contact pad, forming a protective mask in direct contact with the surface of the first insulating layer with an opening in the protective mask extending outside the opening in the first insulating layer, and forming a first conductive layer within the opening in the protective mask and in direct contact with a surface of the first insulating layer and central portion of the first insulating layer and through the opening in the first insulating layer in direct contact with the contact pad.

In another embodiment, the present invention is a semiconductor device comprising a substrate including a contact pad formed on a surface of the substrate. A first insulating layer is formed in direct contact with the surface of the substrate and contact pad with an opening formed in the first insulating layer extending to the contact pad to leave a central portion of the first insulating layer extending from the contact pad. A protective mask is formed in direct contact with the surface of the first insulating layer with an opening in the protective mask extending outside the opening in the first insulating layer. A first conductive layer is formed within the opening in the protective mask and in direct contact with a surface of the first insulating layer and central portion of the first insulating layer and through the opening in the first insulating layer in direct contact with the contact pad.

### BRIEF DESCRIPTION OF THE DRAWINGS

FIG. 1 illustrates a conventional bump interconnect structure;

FIG. 2 illustrates a printed circuit board (PCB) with different types of packages mounted to its surface;

FIGS. 3a-3c illustrate further detail of the representative semiconductor packages mounted to the PCB;

FIGS. 4a-4c illustrate a semiconductor wafer with a plurality of semiconductor die separated by a saw street;

FIGS. 5a-5j illustrate a process of forming a bump interconnect structure with conformal conductive layer over a protruding buffer layer;

FIGS. 6a-6h illustrate another process of forming a bump interconnect structure with conformal conductive layer over a protruding buffer layer; and

FIGS. 7a-7g illustrate a process of forming a bump interconnect structure with an extended conductive layer over a buffer layer.

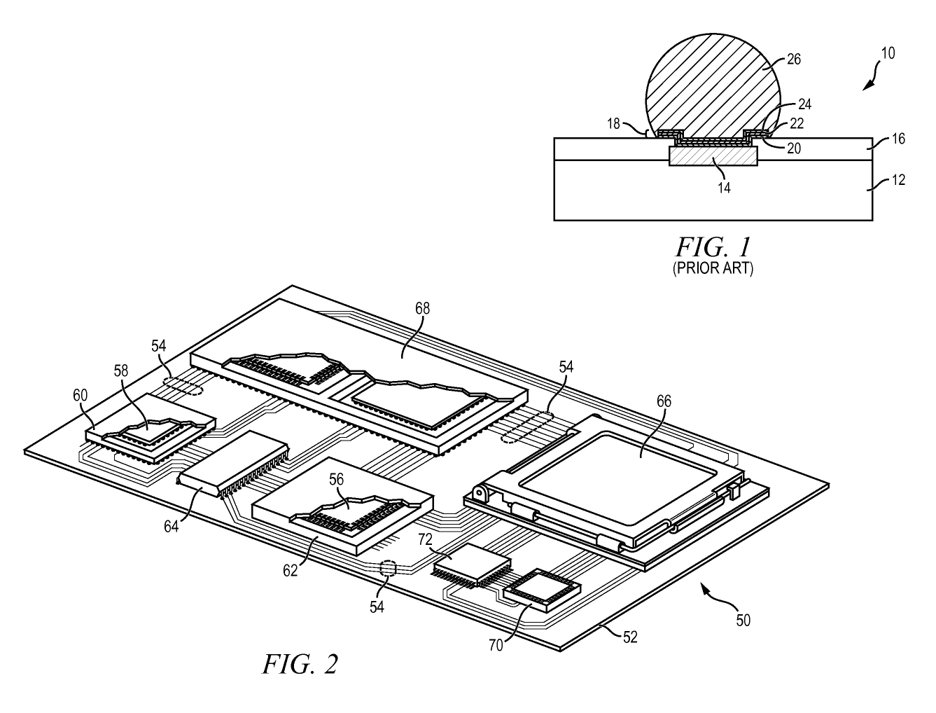

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, resistors, and transformers, create a relationship between voltage and current necessary to perform electrical circuit functions.

Passive and active components are formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices, transforming the semiconductor material into an insulator, conductor, or dynamically changing the semiconductor material conductivity in response to an electric field or base current. Transistors contain regions of varying types and degrees of doping arranged as necessary to enable the transistor to promote or restrict the flow of electrical current upon the application of the electric field or base current.

Active and passive components are formed by layers of materials with different electrical properties. The layers can be formed by a variety of deposition techniques determined in part by the type of material being deposited. For example, thin film deposition can involve chemical vapor deposition (CVD), physical vapor deposition (PVD), electrolytic plating, and electroless plating processes. Each layer is generally patterned to form portions of active components, passive components, or electrical connections between components.

The layers can be patterned using photolithography, which involves the deposition of light sensitive material, e.g., photoresist, over the layer to be patterned. A pattern is transferred from a photomask to the photoresist using light. In one embodiment, the portion of the photoresist pattern subjected to light is removed using a solvent, exposing portions of the underlying layer to be patterned. In another embodiment, the portion of the photoresist pattern not subjected to light, the negative photoresist, is removed using a solvent, exposing portions of the underlying layer to be patterned. The remainder of the photoresist is removed, leaving behind a patterned layer. Alternatively, some types of materials are patterned by directly depositing the material into the areas or voids formed by a previous deposition/etch process using techniques such as electroless and electrolytic plating.

Depositing a thin film of material over an existing pattern can exaggerate the underlying pattern and create a non-uniformly flat surface. A uniformly flat surface is required to produce smaller and more densely packed active and passive components. Planarization can be used to remove material from the surface of the wafer and produce a uniformly flat surface. Planarization involves polishing the surface of the wafer with a polishing pad. An abrasive material and corrosive chemical are added to the surface of the wafer during polishing. The combined mechanical action of the abrasive and corrosive action of the chemical removes any irregular topography, resulting in a uniformly flat surface.

Back-end manufacturing refers to cutting or singulating the finished wafer into the individual die and then packaging the die for structural support and environmental isolation. To singulate the die, the wafer is scored and broken along non-functional regions of the wafer called saw streets or scribes. The wafer is singulated using a laser cutting tool or saw blade. After singulation, the individual die are mounted to a package substrate that includes pins or contact pads for interconnection with other system components. Contact pads formed over the semiconductor die are then connected to contact pads within the package. The electrical connections can be made with solder bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

FIG. 2 illustrates electronic device 50 having a chip carrier substrate or printed circuit board (PCB) 52 with a plurality of semiconductor packages mounted on its surface. Electronic device 50 can have one type of semiconductor package, or multiple types of semiconductor packages, depending on the application. The different types of semiconductor packages are shown in FIG. 2 for purposes of illustration.

Electronic device 50 can be a stand-alone system that uses the semiconductor packages to perform one or more electrical functions. Alternatively, electronic device 50 can be a subcomponent of a larger system. For example, electronic device 50 can be part of a cellular phone, personal digital assistant (PDA), digital video camera (DVC), or other electronic communication device. Alternatively, electronic device 50 can be a graphics card, network interface card, or other signal processing card that can be inserted into a computer. The semiconductor package can include microprocessors, memories, application specific integrated circuits (ASIC), logic circuits, analog circuits, RF circuits, discrete devices, or other semiconductor die or electrical components. Miniaturization and weight reduction are essential for these products to be accepted by the market. The distance between semiconductor devices must be decreased to achieve higher density.

In FIG. 2, PCB 52 provides a general substrate for structural support and electrical interconnect of the semiconductor packages mounted on the PCB. Conductive signal traces 54 are formed over a surface or within layers of PCB 52 using evaporation, electrolytic plating, electroless plating, screen printing, or other suitable metal deposition process. Signal traces 54 provide for electrical communication between each of the semiconductor packages, mounted components, and other external system components. Traces 54 also provide power and ground connections to each of the semiconductor packages.

In some embodiments, a semiconductor device has two packaging levels. First level packaging is a technique for mechanically and electrically attaching the semiconductor die to an intermediate carrier. Second level packaging involves mechanically and electrically attaching the intermediate carrier to the PCB. In other embodiments, a semiconductor device may only have the first level packaging where the die is mechanically and electrically mounted directly to the PCB.

For the purpose of illustration, several types of first level packaging, including bond wire package 56 and flipchip 58, are shown on PCB 52. Additionally, several types of second level packaging, including ball grid array (BGA) 60, bump chip carrier (BCC) 62, dual in-line package (DIP) 64, land grid array (LGA) 66, multi-chip module (MCM) 68, quad flat non-leaded package (QFN) 70, and quad flat package 72, are shown mounted on PCB 52. Depending upon the system requirements, any combination of semiconductor packages, configured with any combination of first and second level packaging styles, as well as other electronic components, can be connected to PCB 52. In some embodiments, electronic device 50 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using cheaper components and a streamlined manufacturing process. The resulting devices are less likely to fail and less expensive to manufacture resulting in a lower cost for consumers.

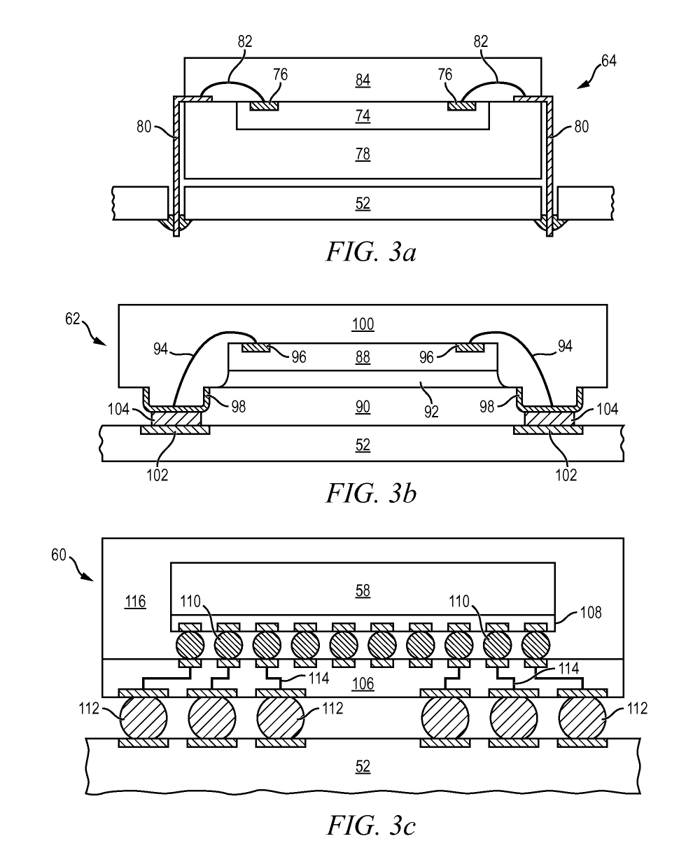

FIGS. 3a-3c show exemplary semiconductor packages. FIG. 3a illustrates further detail of DIP 64 mounted on PCB 52. Semiconductor die 74 includes an active region containing analog or digital circuits implemented as active devices, passive devices, conductive layers, and dielectric layers formed within the die and are electrically interconnected according to the electrical design of the die. For example, the circuit can include one or more transistors, diodes, inductors, capacitors, resistors, and other circuit elements formed within the active region of semiconductor die 74. Contact pads 76 are one or more layers of conductive material, such as aluminum (Al), copper (Cu), tin (Sn), nickel (Ni), gold (Au), or silver (Ag), and are electrically connected to the circuit elements formed within semiconductor die 74. During assembly of DIP 64, semiconductor die 74 is mounted to an intermediate carrier 78 using a gold-silicon eutectic layer or adhesive material such as thermal epoxy or epoxy resin. The package body includes an insulative packaging material such as polymer or ceramic. Conductor leads 80 and bond wires 82 provide electrical interconnect between semiconductor die 74 and PCB 52. Encapsulant 84 is deposited over the package for environmental protection by preventing moisture and particles from entering the package and contaminating die 74 or bond wires 82.

FIG. 3b illustrates further detail of BCC 62 mounted on PCB 52. Semiconductor die 88 is mounted over carrier 90 using an underfill or epoxy-resin adhesive material 92. Bond wires 94 provide first level packaging interconnect between contact pads 96 and 98. Molding compound or encapsulant 100 is deposited over semiconductor die 88 and bond wires 94 to provide physical support and electrical isolation for the device. Contact pads 102 are formed over a surface of PCB 52 using a suitable metal deposition process such as electrolytic plating or electroless plating to prevent oxidation. Contact pads 102 are electrically connected to one or more conductive signal traces 54 in PCB 52. Bumps 104 are formed between contact pads 98 of BCC 62 and contact pads 102 of PCB 52.

In FIG. 3c, semiconductor die 58 is mounted face down to intermediate carrier 106 with a flipchip style first level packaging. Active region 108 of semiconductor die 58 contains analog or digital circuits implemented as active devices, passive devices, conductive layers, and dielectric layers formed according to the electrical design of the die. For example, the circuit can include one or more transistors, diodes, inductors, capacitors, resistors, and other circuit elements within active region 108. Semiconductor die 58 is electrically and mechanically connected to carrier 106 through bumps 110.

BGA 60 is electrically and mechanically connected to PCB 52 with a BGA style second level packaging using bumps 112. Semiconductor die 58 is electrically connected to conductive signal traces 54 in PCB 52 through bumps 110, signal lines 114, and bumps 112. A molding compound or encapsulant 116 is deposited over semiconductor die 58 and carrier 106 to provide physical support and electrical isolation for the device. The flipchip semiconductor device provides a short electrical conduction path from the active devices on semiconductor die 58 to conduction tracks on PCB 52 in order to reduce signal propagation distance, lower capacitance, and improve overall circuit performance. In another embodiment, the semiconductor die 58 can be mechanically and electrically connected directly to PCB 52 using flipchip style first level packaging without intermediate carrier 106.

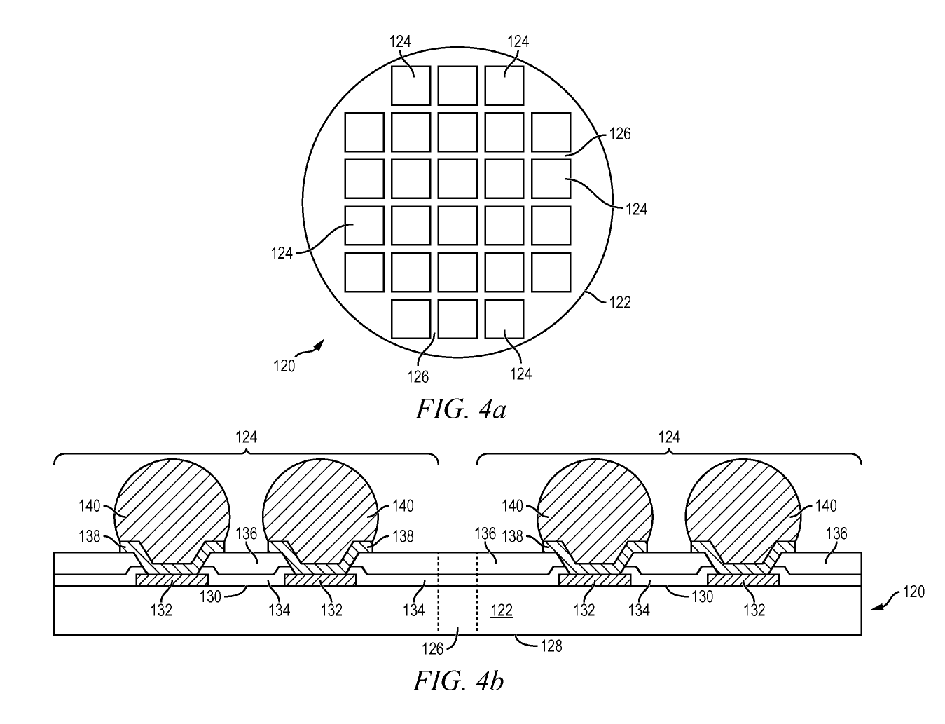

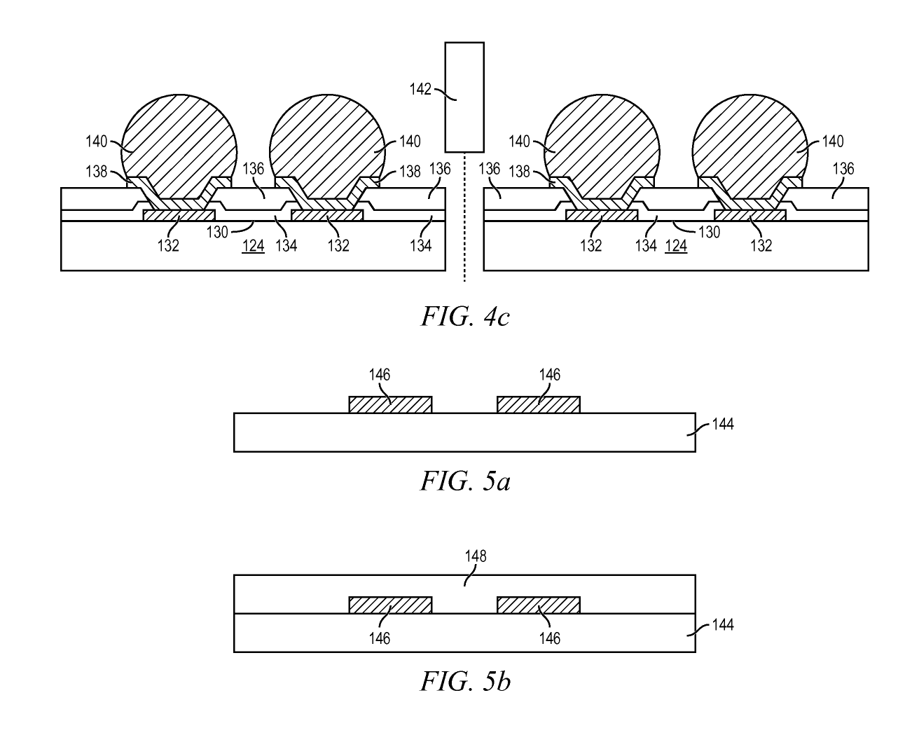

FIG. 4a shows a semiconductor wafer 120 with a base substrate material 122, such as silicon, germanium, gallium arsenide, indium phosphide, or silicon carbide, for structural support. A plurality of semiconductor die or components 124 is formed on wafer 120 separated by a non-active, inter-die wafer area or saw street 126 as described above. Saw street 126 provides cutting areas to singulate semiconductor wafer 120 into individual semiconductor die 124. In one embodiment, semiconductor die 124 may have dimensions ranging from 2×2 millimeters (mm) to 15×15 mm.

FIG. 4b shows a cross-sectional view of a portion of semiconductor wafer 120. Each semiconductor die 124 has a back surface 128 and active surface 130 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 130 to implement analog circuits or digital circuits, such as digital signal processor (DSP), ASIC, memory, or other signal processing circuit. Semiconductor die 124 may also contain integrated passive devices (IPDs), such as inductors, capacitors, and resistors, for RF signal processing. In one embodiment, semiconductor die 124 is a flipchip type die.

An electrically conductive layer 132 is formed over active surface 130 using PVD, CVD, electrolytic plating, electroless plating process, or other suitable metal deposition process. Conductive layer 132 can be one or more layers of Al, Cu, Sn, Ni, Au, Ag, or other suitable electrically conductive material. Conductive layer 132 operates as contact pads electrically connected to the circuits on active surface 130. Contact pads 132 can be disposed side-by-side a first distance from the edge of semiconductor die 124, as shown in FIG. 4b. Alternatively, contact pads 132 can be offset in multiple rows such that a first row of contact pads is disposed a first distance from the edge of the die, and a second row of contact pads alternating with the first row is disposed a second distance from the edge of the die.

An insulating or passivation layer 134 is formed over active surface 130 and conductive layer 132 using PVD, CVD, printing, spin coating, spray coating, sintering or thermal oxidation. The insulating layer 134 contains one or more layers of silicon dioxide (SiO2), silicon nitride (Si3N4), silicon oxynitride (SiON), tantalum pentoxide (Ta2O5), aluminum oxide (Al2O3), or other material having similar insulating and structural properties. A portion of insulating layer 134 is removed by an etching process to expose conductive layer 132.

An insulating or buffering layer 136 is formed over insulating layer 134 and the exposed conductive layer 132 using PVD, CVD, printing, spin coating, spray coating, sintering or thermal oxidation. In one embodiment, insulating layer 136 contains one or more layers of with benzocyclobutene (BCB), polyimide (PI), polybenzoxazoles (PBO), or other suitable material. Alternatively, insulating layer 136 can contain one or more layers of SiO2, Si3N4, SiON, Ta2O5, Al2O3, or other material having similar insulating and structural properties. A portion of insulating layer 134 is removed by an etching process to expose conductive layer 132.

An electrically conductive layer 138 is formed over the exposed conductive layer 132 and insulating layer 136 using a patterning and metal deposition process such as printing, PVD, CVD, sputtering, electrolytic plating, and electroless plating. In one embodiment, conductive layer 138 is Ti, titanium tungsten (TiW), or chromium (Cr) formed by sputtering. Alternatively, conductive layer 138 can be one or more layers of Al, Cu, Sn, Ni, Au, Ag, or other suitable electrically conductive material. Conductive layer 138 follows the contours of insulation layer 136 and conductive layer 132. Conductive layer 138 operates as an under bump metallization (UBM) layer for a later formed bump. Conductive layer 138 is electrically connected to conductive layer 132.

An electrically conductive bump material is deposited over UBM 138 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to UBM 138 using a suitable attachment or bonding process. In one embodiment, the bump material is reflowed by heating the material above its melting point to form spherical balls or bumps 140. In some applications, bumps 140 are reflowed a second time to improve electrical contact to UBM 138. Bumps 140 can also be compression bonded to UBM 138. Bumps 140 represent one type of interconnect structure that can be formed over UBM 138. The interconnect structure can also use stud bump, micro bump, or other electrical interconnect.

In FIG. 4c, semiconductor wafer 120 is singulated through saw street 126 using a saw blade or laser cutting tool 142 into individual semiconductor die 124.

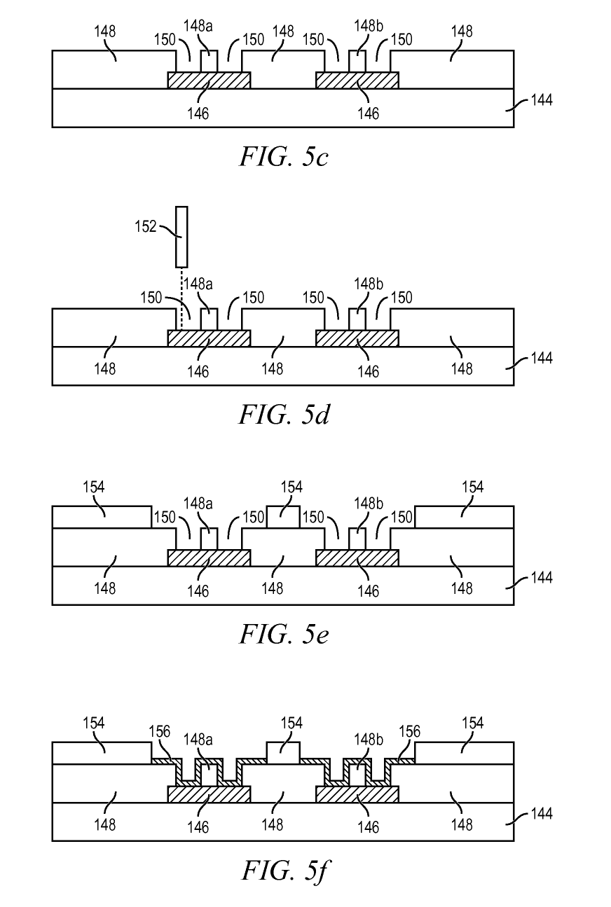

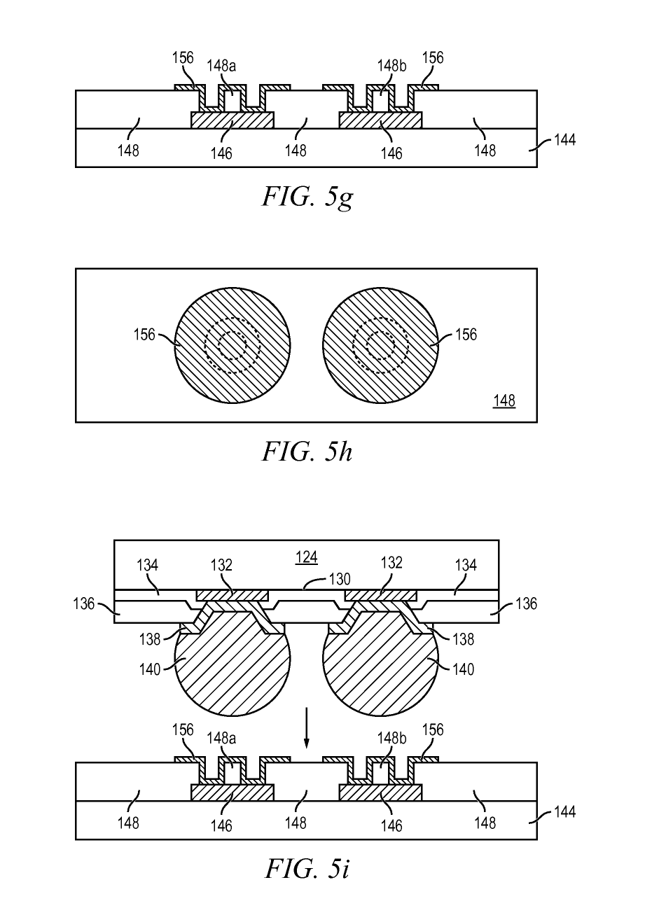

FIGS. 5a-5j illustrate, in relation to FIGS. 2 and 3a-3c, a process of forming a bump interconnect structure with a conformal conductive layer over a buffer layer. FIG. 5a shows a base substrate or PCB 144 with an electrically conductive layer 146 formed over a surface of the base substrate using PVD, CVD, electrolytic plating, electroless plating process, or other suitable metal deposition process. Conductive layer 146 can be one or more layers of Al, Cu, Sn, Ni, Au, Ag, or other suitable electrically conductive material. Conductive layer 146 operates as contact pads or conductive traces for later-mounted semiconductor die 124.

In FIG. 5b, a solder resist or insulating layer 148 is formed over substrate 144 and conductive layer 146 using PVD, CVD, printing, spin coating, spray coating, sintering or thermal oxidation. The insulating layer 148 can contain one or more layers of SiO2, Si3N4, SiON, Ta2O5, Al2O3, or photo-sensitive material. In one embodiment, insulating layer 148 has a thickness of 10-30 micrometers (μm). The insulating layer 148 covers a top surface of substrate 144, sidewall of conductive layer 146, and top surface of conductive layer 146. A top surface of insulating layer 148 is substantially flat. A portion of insulating layer 148 is removed by patterning, exposure to ultraviolet (UV) light, and developing to form a toroidal or circular solder resist opening (SRO) 150 and expose conductive layer 146, as shown in FIG. 5c. In another example, the solder resist can include a DFR material with a PET support film. The DFR is laminated, undergoes an edge rinse, is aligned over conductive layer 146, the PET support film is removed, and the DFR material is then developed. The DFR can be irradiated using a visible light laser to form a desired pattern. The irradiated DFR material is then subjected to a developer which selectively dissolves non-irradiated portions of the photoresist material and leaves the irradiated portions of the photoresist material intact. After removing a portion of insulating layer 148, SRO 150 has vertical sidewalls and retains protruding central islands 148a-148b of insulating layer 148 within the SRO. In one embodiment, the SRO size can be in the range of 40-60 micrometers (μm) or 80-100 μm.

Alternatively, toroidal or circular SRO 150 can be formed by laser direct ablation (LDA) using laser 152 to expose conductive layer 146 and leave protruding central islands 148a-148b in applications requiring finer SRO dimensions, as shown in FIG. 5d.

In FIG. 5e, a protective mask layer 154 is formed over insulating layer 148 with openings to expose conductive layer 146, central islands 148a-148b, and a portion of insulating layer 148 around SRO 150. Mask layer 154 can be BCB, PI, PBO, or other suitable insulating material.

In FIG. 5f, an electrically conductive layer 156 is conformally applied over conductive layer 146, central islands 148a-148b, and the portion of insulating layer 148 in and around SRO 150 using PVD, CVD, electrolytic plating, electroless plating process, or other suitable metal deposition process. Conductive layer 156 can be one or more layers of Al, Cu, Sn, Ni, Au, Ag, or other suitable electrically conductive material. In one embodiment, conductive layer 156 has an electroless plated palladium (Pd) seed layer and electroplated Cu layer. The conformal deposition of conductive layer 156, i.e., following the contour of insulating layer 148, including along the sidewalls of SRO 150 and over central islands 148a-148b of insulating layer 148 inside the SRO, increases the surface area of the conductive layer. The protective mask layer 154 is removed in FIG. 5g. FIG. 5h shows a top view of conductive layer 156 formed over insulating layer 148. In one embodiment, conductive layer 156 formed over conductive layer 146 on substrate 144 constitutes a surface mount device (SMD) contact pad.

In FIG. 5i, semiconductor die 124 from FIGS. 4a-4c is oriented over and mounted to substrate 144 using a pick and place operation. FIG. 5j shows semiconductor die 124 mounted to substrate 144 with bumps 140 electrically connected to conductive layer 156. In one embodiment, bumps 140 can be reflow-bonded or compression bonded to conductive layer 156 as a solder plated on pad (SPOP) structure on an SMD pad. The central islands 148a-148b of insulating material 148 within toroidal or circular SRO 150 acts as a buffer layer for stress relief on bumps 140 which reduces bump cracking and die cracking. The insulating layer 136 provides additional stress relief on the die side of bumps 140. With the conformal deposition of conductive layer 156 over SRO 150 and central islands 148a-148b of insulating layer 148, conductive layer 156 extends into a central portion of bumps 140 and increases the contact surface area between bumps 140 and conductive layer 156 for enhanced wettability and reliability for higher manufacturing yield. Conductive layer 156 can achieve a fine interconnect pitch with proper SRO formation, as described in FIGS. 5c-5d.

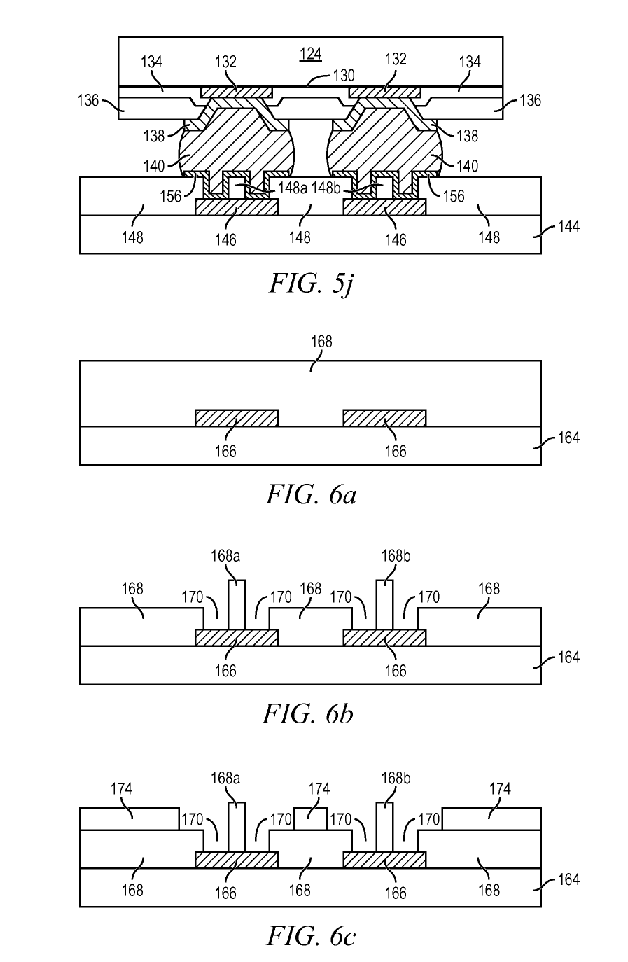

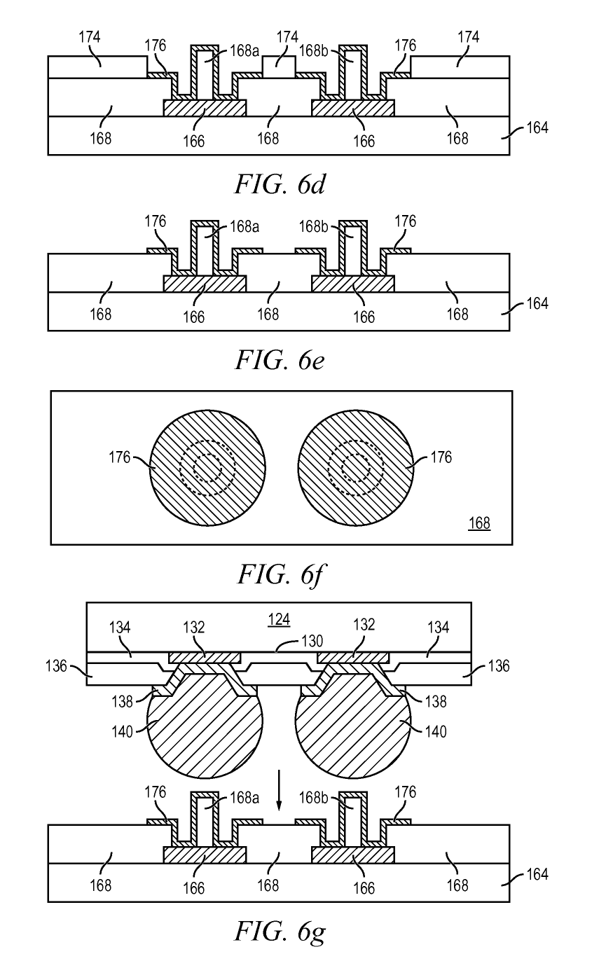

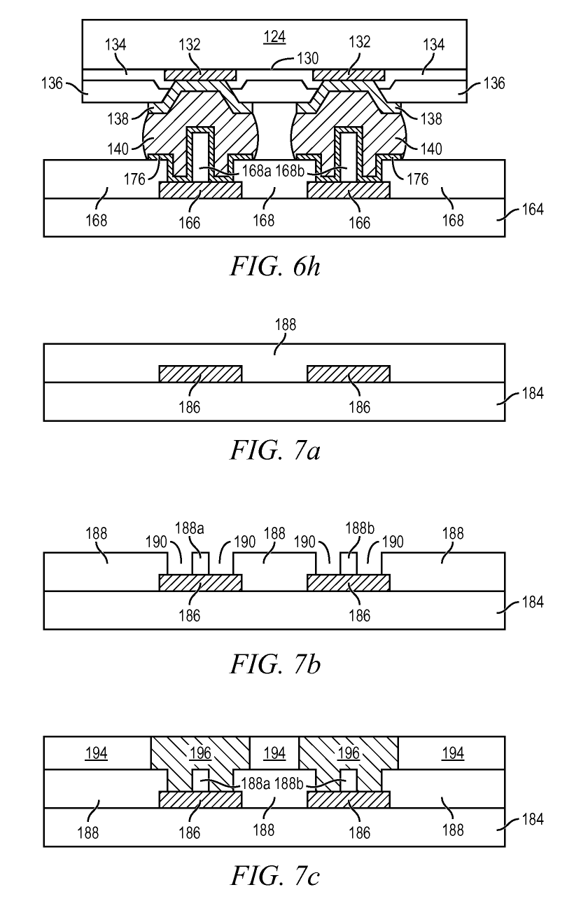

FIGS. 6a-6h illustrate, in relation to FIGS. 2 and 3a-3c, another process of forming interconnect structure with conformal conductive layer over a protruding buffer layer. FIG. 6a shows a base substrate or PCB 164 with an electrically conductive layer 166 formed over a surface of the base substrate using PVD, CVD, electrolytic plating, electroless plating process, or other suitable metal deposition process. Conductive layer 166 can be one or more layers of Al, Cu, Sn, Ni, Au, Ag, or other suitable electrically conductive material. Conductive layer 166 operates as contact pads or conductive traces for later mounted semiconductor die 124.

A solder resist or insulating layer 168 is formed over substrate 164 and conductive layer 166 using PVD, CVD, printing, spin coating, spray coating, sintering or thermal oxidation. The insulating layer 168 can contain one or more layers of SiO2, Si3N4, SiON, Ta2O5, Al2O3, or photo-sensitive material. In one embodiment, insulating layer 168 has a thickness of 10-30 μm. The insulating layer 168 covers a top surface of substrate 164, sidewall of conductive layer 166, and top surface of conductive layer 166. A top surface of insulating layer 168 is substantially flat. A portion of insulating layer 168 is removed by patterning, exposure to UV light, and developing to form a circular SRO 170 and expose conductive layer 166, as shown in FIG. 6b. In another example, the solder resist can include a DFR material with a PET support film. The DFR is laminated, undergoes an edge rinse, is aligned over conductive layer 166, the PET support film is removed, and the DFR material is then developed. The DFR can be irradiated using a visible light laser to form a desired pattern. The irradiated DFR material is then subjected to a developer, which selectively dissolves non-irradiated portions of the photoresist material and leaves the irradiated portions of the photoresist material intact. After removing a portion of insulating layer 168, SRO 170 has vertical sidewalls and retains a protruding central islands 168a-168b of insulating layer 168 within the SRO. The protruding central islands 168a-168b extends substantially above, e.g., 40-80 μm, the portions of insulating layer 168 outside SRO 170. In one embodiment, the SRO size can be in the range of 40-60 μm or 80-100 μm. Alternatively, SRO 170 can be formed by LDA to expose conductive layer 166 and leave protruding central islands 168a-168b in applications requiring finer SRO dimensions, similar to FIG. 5d.

In FIG. 6c, a protective mask layer 174 is formed over insulating layer 168 with openings to expose conductive layer 166, protruding central islands 168a-168b, and a portion of insulating layer 168 around SRO 170. Mask layer 174 can be BCB, PI, PBO, or other suitable insulating material.

In FIG. 6d, an electrically conductive layer 176 is conformally applied over conductive layer 166, protruding central islands 168a-168b, and the portion of insulating layer 168 in and around SRO 170 using PVD, CVD, electrolytic plating, electroless plating process, or other suitable metal deposition process. Conductive layer 176 can be one or more layers of Al, Cu, Sn, Ni, Au, Ag, or other suitable electrically conductive material. In one embodiment, conductive layer 176 has an electroless plated Pd seed layer, and electroplated Cu layer. The conformal deposition of conductive layer 176, i.e., following the contour of insulating layer 168, including along the sidewalls of SRO 170 and over central islands 168a-168b of insulating layer 168 inside the SRO, increases the surface area of the conductive layer. The protective mask layer 174 is removed in FIG. 6e. FIG. 6f shows a top view of conductive layer 176 formed over insulating layer 168. In one embodiment, conductive layer 176 formed over conductive layer 166 on substrate 164 constitutes a SMD contact pad.

In FIG. 6g, semiconductor die 124 from FIGS. 4a-4c is oriented over and mounted to substrate 164 using a pick and place operation. FIG. 6h shows semiconductor die 124 mounted to substrate 164 with bumps 140 electrically connected to conductive layer 176. In one embodiment, bumps 140 can be reflow-bonded or compression bonded to conductive layer 176 as a SPOP structure on an SMD pad. The central islands 168a-168b of insulating material 168 within SRO 170 acts as a buffer layer to absorb stress on bumps 140 which reduces bump cracking and die cracking. The insulating layer 136 provides additional stress relief on the die side of bumps 140. With the conformal deposition of conductive layer 176 over the SRO 170 and protruding central islands 168a-168b of insulating layer 168, conductive layer 176 extends into a central portion of bumps 140 and increases the contact surface area between bumps 140 and conductive layer 176 for enhanced wettability and reliability for higher manufacturing yield. Conductive layer 176 can achieve a fine interconnect pitch with proper SRO formation.

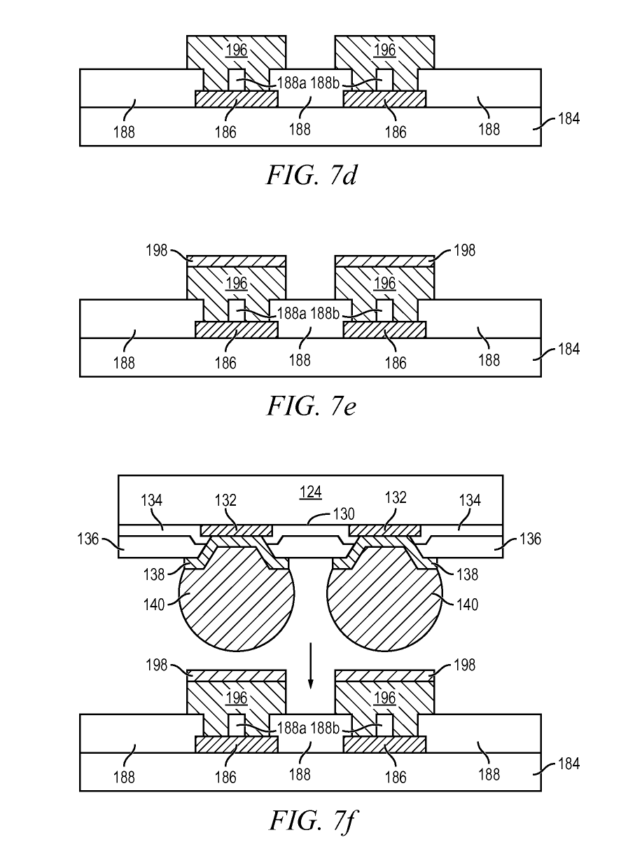

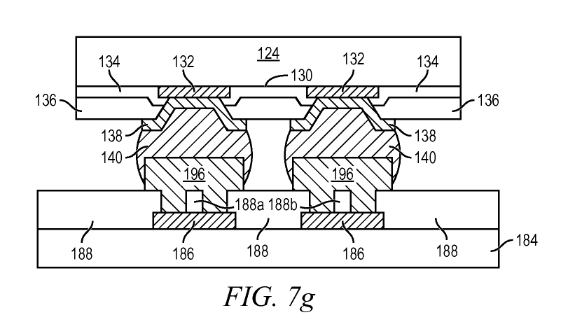

FIGS. 7a-7g illustrate, in relation to FIGS. 2 and 3a-3c, a process of forming interconnect structure with an extended conductive layer over a buffer layer. FIG. 7a shows a base substrate or PCB 184 with an electrically conductive layer 186 formed over a surface of the base substrate using PVD, CVD, electrolytic plating, electroless plating process, or other suitable metal deposition process. Conductive layer 186 can be one or more layers of Al, Cu, Sn, Ni, Au, Ag, or other suitable electrically conductive material. Conductive layer 186 operates as contact pads or conductive traces for later mounted semiconductor die 124.

A solder resist or insulating layer 188 is formed over substrate 184 and conductive layer 186 using PVD, CVD, printing, spin coating, spray coating, sintering or thermal oxidation. The insulating layer 188 can contain one or more layers of SiO2, Si3N4, SiON, Ta2O5, Al2O3, or photo-sensitive material. In one embodiment, insulating layer 188 has a thickness of 10-30 μm. The insulating layer 188 covers a top surface of substrate 184, sidewall of conductive layer 186, and top surface of conductive layer 186. A top surface of insulating layer 188 is substantially flat. A portion of insulating layer 188 is removed by patterning, exposure to UV light, and developing to form a toroidal or circular SRO 190 and expose conductive layer 186, as shown in FIG. 7b. In another example, the solder resist can include a DFR material with a PET support film. The DFR is laminated, undergoes an edge rinse, is aligned over conductive layer 186, the PET support film is removed, and the DFR material is then developed. The DFR can be irradiated using a visible light laser to form a desired pattern. The irradiated DFR material is then subjected to a developer, which selectively dissolves non-irradiated portions of the photoresist material and leaves the irradiated portions of the photoresist material intact. After removing a portion of insulating layer 188, SRO 190 has vertical sidewalls and retains a protruding central islands 188a-188b of insulating layer 188 within the SRO. In one embodiment, the SRO size can be in the range of 40-60 μm or 80-100 μm. Alternatively, toroidal or circular SRO 190 can be formed by LDA to expose conductive layer 186 and leave protruding central islands 188a-188b in applications requiring finer SRO dimensions, similar to FIG. 5d.

In FIG. 7c, a protective mask layer 194 is formed over insulating layer 188 with openings to expose conductive layer 186, protruding central islands 188a-188b, and a portion of insulating layer 188 around SRO 190. Mask layer 194 can be BCB, PI, PBO, or other suitable insulating material.

An electrically conductive layer 196 is formed over conductive layer 186, protruding central islands 188a-188b, and the portion of insulating layer 188 in and around SRO 190 using PVD, CVD, electrolytic plating, electroless plating process, or other suitable metal deposition process. Conductive layer 196 can be one or more layers of Al, Cu, Sn, Ni, Au, Ag, or other suitable electrically conductive material. In one embodiment, conductive layer 196 has an electroless plated Pd seed layer, and electroplated Cu layer. Conductive layer 196 extends above insulating layer 188 by a height of 40-80 μm. The extended height of conductive layer 196 over conductive layer 186, central islands 188a-188b, and the portion of insulating layer 188 in and around SRO 190 increases the surface area of the conductive layer. The protective mask layer 194 is removed in FIG. 7d. A wetting layer 198 is formed over conductive layer 196 in FIG. 7e. In one embodiment, wetting layer 198 is a solder cap.

In FIG. 7f, semiconductor die 124 from FIGS. 4a-4c is oriented over and mounted to substrate 184 using a pick and place operation. FIG. 7g shows semiconductor die 124 mounted to substrate 184 with bumps 140 electrically connected to conductive layer 196. In one embodiment, bumps 140 can be reflow-bonded or compression bonded to conductive layer 196. The central islands 188a-188b of insulating material 188 within toroidal or circular SRO 190 acts as a buffer layer to absorb stress on bumps 140 which reduces bump cracking and die cracking. The insulating layer 136 provides additional stress relief on the die side of bumps 140. The extended conductive layer 196 over SRO 190 and protruding central islands 188a-188b of insulating layer 188 increases the contact surface area between bumps 140 and conductive layer 196 for enhanced wettability and reliability for higher manufacturing yield. Conductive layer 196 can achieve a fine interconnect pitch with proper SRO formation.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a substrate including a contact pad formed on a surface of the substrate;
forming a first insulating layer in direct contact with the surface of the substrate and contact pad;
removing a first portion of the first insulating layer to form an opening within a boundary of the contact pad and extending to the contact pad while leaving a central portion of the first insulating layer extending from the contact pad, and removing a second portion of the first insulating layer to leave a surface of the first insulating layer extending outwardly from the opening below a height of the central portion of the first insulating layer;
forming a protective mask in direct contact with the surface of the first insulating layer with an opening in the protective mask extending outside the opening in the first insulating layer;
conformally applying a first conductive layer within the opening in the protective mask and in direct contact with the surface and central portion of the first insulating layer and through the opening in the first insulating layer in direct contact with the contact pad;
providing a semiconductor die including a bump formed over the semiconductor die; and
bonding the bump to the first conductive layer with the central portion of the first insulating layer extending into the bump.

2. The method of claim 1, wherein the opening in the first insulating layer includes a circular or toroidal shape.

3. The method of claim 1, wherein the first insulating layer includes solder resist material.

4. The method of claim 1, further including forming the opening in the first insulating layer using laser direct ablation.

5. The method of claim 1, further including removing the protective mask.

6. The method of claim 1, further including:
forming a second conductive layer over a surface of the semiconductor die;
forming a second insulating layer over the surface of the semiconductor die;
forming a third conductive layer over the second conductive layer and second insulating layer; and
forming the bump over the third conductive layer.

7. A method of making a semiconductor device, comprising:
providing a substrate including a contact pad formed on a surface of the substrate;
forming a first insulating layer in direct contact with the surface of the substrate and contact pad;
removing a portion of the first insulating layer to form an opening extending to the contact pad while leaving a central portion of the first insulating layer extending from the contact pad;
forming a protective mask in direct contact with the surface of the first insulating layer with an opening in the protective mask extending outside the opening in the first insulating layer;
depositing a conductive material to completely fill the opening in the protective mask from the contact pad to a surface of the protective mask; and
disposing a semiconductor die over the substrate and electrically connected to the conductive material.

8. The method of claim 7, wherein the opening in the first insulating layer includes a circular or toroidal shape.

9. The method of claim 7, wherein the first insulating layer includes solder resist material.

10. The method of claim 7, further including forming the opening in the first insulating layer using laser direct ablation.

11. The method of claim 7, further including removing the protective mask.

12. The method of claim 7, further including forming a conductive layer over the conductive material.

13. The method of claim 7, further including:
forming a first conductive layer over a surface of the semiconductor die;
forming a second insulating layer over the surface of the semiconductor die;
forming a second conductive layer over the first conductive layer and second insulating layer; and
forming the bump over the second conductive layer.

14. A method of making a semiconductor device, comprising:
providing a substrate including a contact pad formed on a surface of the substrate;
forming a first insulating layer in direct contact with the surface of the substrate and contact pad;
removing a first portion of the first insulating layer to form an opening extending to the contact pad while leaving a central portion of the first insulating layer extending from the contact pad;
forming a protective mask in direct contact with the surface of the first insulating layer with an opening in the protective mask extending outside the opening in the first insulating layer; and
forming a first conductive layer within the opening in the protective mask and in direct contact with a surface of the first insulating layer and central portion of the first insulating layer and through the opening in the first insulating layer in direct contact with the contact pad.

15. The method of claim 14, further including disposing a semiconductor die over the substrate and electrically connected to the first conductive layer.

16. The method of claim 14, further including removing a second portion of the first insulating layer to leave a surface of the first insulating layer extending outwardly from the opening below a height of the central portion of the first insulating layer.

17. The method of claim 16, further including:
providing a semiconductor die including a bump formed over the semiconductor die; and
bonding the bump to the first conductive layer with the central portion of the first insulating layer extending into the bump.

18. The method of claim 14, further including forming the opening in the first insulating layer using laser direct ablation.

19. The method of claim 14, further including removing the protective mask.

20. The method of claim 14, wherein the opening in the first insulating layer includes a circular or toroidal shape.

21. A semiconductor device, comprising:
a substrate including a contact pad formed on a surface of the substrate;
a first insulating layer formed in direct contact with the surface of the substrate and contact pad with an opening formed in the first insulating layer extending to the contact pad to leave a central portion of the first insulating layer extending from the contact pad;
a protective mask formed in direct contact with the surface of the first insulating layer with an opening in the protective mask extending outside the opening in the first insulating layer; and
a first conductive layer formed within the opening in the protective mask and in direct contact with a surface of the first insulating layer and central portion of the first insulating layer and through the opening in the first insulating layer in direct contact with the contact pad.

22. The semiconductor device of claim 20, wherein the opening in the first insulating layer includes a circular or toroidal shape.

23. The semiconductor device of claim 20, wherein the first insulating layer includes solder resist material.

24. The semiconductor device of claim 20, further including a semiconductor die disposed over the substrate and electrically connected to the first conductive layer.

25. The semiconductor device of claim 24, further including:
a second conductive layer formed over a surface of the semiconductor die;
a second insulating layer formed over the surface of the semiconductor die; and
a third conductive layer formed over the second conductive layer and second insulating layer, wherein the bump is formed over the third conductive layer.
